(19) United States
(12) Patent Application Publication
(10) Pub. No.: US 2026/0252763 A1
(43) Pub. Date: Aug. 27, 2026

(54) HYBRID DISCRIMINATIVE AND GENERATIVE MODEL ARCHITECTURE FOR CONTEXTUAL REPLAY TESTING IN COMPLEX SYSTEMS

(71) Applicant: KX Systems, Inc., New York, NY (US)

(72) Inventor: Ashok T. Reddy, Brooklyn, NY (US)

(21) Appl. No.: 19/061,554

(22) Filed: Feb. 24, 2025

(51) Int. Cl. G06F 30/27; G06F 30/17

(52) U.S. Cl. CPC G06F 30/27; G06F 30/17

(57) ABSTRACT

A set of unstructured content elements related to a particular complex system are processed with a machine-learned embedding model to obtain a first set of vector embeddings. A set of structured data elements comprising measurements of the particular complex system are processed with the embedding model to obtain a second set of vector embeddings. A contextual state label indicative of a particular system state is computed for each of the set of unstructured content elements and the set of structured data elements. The vector embeddings are stored to a unified hybrid vector database. Determinant context variables are identified for the complex system. A first subset of the vector embeddings and the determinant context variables are processed with a machine-learned generative model to generate a first simulation of the particular complex system for evaluating an optimization strategy for the particular complex system.

### BACKGROUND

Machine learning techniques are used to learn complex patterns from data by automatically adapting internal parameters to optimize specific objectives or tasks. Such techniques can be broadly categorized into discriminative models and generative models. Discriminative models focus on understanding the boundary or relationship between input data and the associated output labels, while generative models aim to learn the underlying distribution of the data itself, effectively modeling how the data is produced. By employing these approaches, machine learning systems can perform tasks such as classification, prediction, or pattern recognition with minimal human intervention, leveraging computational algorithms that continually refine their performance through exposure to new examples.

### SUMMARY

One example aspect of the present disclosure is directed to a method. The method includes processing, by a computing system comprising one or more processor devices, a set of unstructured content elements with a machine-learned embedding model to obtain a first set of vector embeddings, wherein the set of unstructured content elements relates to a particular complex system. The method includes processing, by the computing system, a set of structured data elements with the machine-learned embedding model to obtain a second set of vector embeddings, wherein each of the set of structured data elements comprises a measurement of the particular complex system. The method includes computing, by the computing system with a machine-learned discriminative model, a contextual state label for each of the set of unstructured content elements and the set of structured data elements, wherein each contextual state label is indicative of a particular system state of a plurality of system states of the particular complex system. The method includes storing, by the computing system, a plurality of vector embeddings comprising the first set of vector embeddings and the second set of vector embeddings to a unified hybrid vector database, the unified hybrid vector database being operable to index vector embeddings generated from both structured data and unstructured data. The method includes identifying, by the computing system, one or more determinant context variables for the complex system, wherein the plurality of determinant contextual variables are at least partially determinant of the plurality of system states of the particular complex system. The method includes processing, by the computing system, a first subset of the plurality of vector embeddings and the one or more determinant context variables with a machine-learned generative model to generate a first simulation of the particular complex system for evaluating an optimization strategy for the particular complex system, the first simulation of the particular complex system comprising a modified value for a first determinant context variable of the one or more determinant context variables.

Another example aspect of the present disclosure is directed to a computing system comprising one or more processor devices. The one or more processor devices are to process a set of unstructured content elements with a machine-learned embedding model to obtain a first set of vector embeddings, wherein the set of unstructured content elements relates to a particular complex system. The one or more processor devices are to process a set of structured data elements with the machine-learned embedding model to obtain a second set of vector embeddings, wherein each of the set of structured data elements comprises a measurement of the particular complex system. The one or more processor devices are to compute, with a machine-learned discriminative model, a contextual state label for each of the set of unstructured content elements and the set of structured data elements, wherein each contextual state label is indicative of a particular system state of a plurality of system states of the particular complex system. The one or more processor devices are to store a plurality of vector embeddings comprising the first set of vector embeddings and the second set of vector embeddings to a unified hybrid vector database, the unified hybrid vector database being operable to index vector embeddings generated from both structured data and unstructured data. The one or more processor devices are to identify one or more determinant context variables for the complex system, wherein the plurality of determinant contextual variables are at least partially determinant of the plurality of system states of the particular complex system. The one or more processor devices are to process a first subset of the plurality of vector embeddings and the one or more determinant context variables with a machine-learned generative model to generate a first simulation of the particular complex system for evaluating an optimization strategy for the particular complex system, the first simulation of the particular complex system comprising a modified value for a first determinant context variable of the one or more determinant context variables.

Another example aspect of the present disclosure is directed to a non-transitory computer-readable storage medium that includes executable instructions. The executable instructions are to cause one or more processor devices to process a set of unstructured content elements with a machine-learned embedding model to obtain a first set of vector embeddings, wherein the set of unstructured content elements relates to a particular complex system. The executable instructions are to cause the one or more processor devices to process a set of structured data elements with the machine-learned embedding model to obtain a second set of vector embeddings, wherein each of the set of structured data elements comprises a measurement of the particular complex system. The executable instructions are to cause the one or more processor devices to compute, with a machine-learned discriminative model, a contextual state label for each of the set of unstructured content elements and the set of structured data elements, wherein each contextual state label is indicative of a particular system state of a plurality of system states of the particular complex system. The executable instructions are to cause the one or more processor devices to store a plurality of vector embeddings comprising the first set of vector embeddings and the second set of vector embeddings to a unified hybrid vector database, the unified hybrid vector database being operable to index vector embeddings generated from both structured data and unstructured data. The executable instructions are to cause the one or more processor devices to identify one or more determinant context variables for the complex system, wherein the plurality of determinant contextual variables are at least partially determinant of the plurality of system states of the particular complex system. The executable instructions are to cause the one or more processor devices to process a first subset of the plurality of vector embeddings and the one or more determinant context variables with a machine-learned generative model to generate a first simulation of the particular complex system for evaluating an optimization strategy for the particular complex system, the first simulation of the particular complex system comprising a modified value for a first determinant context variable of the one or more determinant context variables.

Individuals will appreciate the scope of the disclosure and realize additional aspects thereof after reading the following detailed description of the examples in association with the accompanying drawing figures.

### BRIEF DESCRIPTION OF THE DRAWINGS

The accompanying drawing figures incorporated in and forming a part of this specification illustrate several aspects of the disclosure and, together with the description, serve to explain the principles of the disclosure.

FIG. 1 is a block diagram of a computing environment suitable for implementing a hybrid discriminative and generative model architecture for contextual replay testing in complex systems according to some implementations of the present disclosure.

FIG. 2 depicts a flow chart diagram of an example method for contextual replay testing for complex systems using a hybrid discriminative and generative model architecture according to some implementations of the present disclosure.

FIG. 3A depicts a block diagram of an example computing system that performs contextual replay testing according to example embodiments of the present disclosure.

FIG. 3B depicts a block diagram of an example computing device that performs contextual replay testing according to example embodiments of the present disclosure.

FIG. 3C depicts a block diagram of an example computing device that performs training of generative and discriminative models according to example embodiments of the present disclosure.

### DETAILED DESCRIPTION

The examples set forth below represent the information to enable individuals to practice the examples and illustrate the best mode of practicing the examples. Upon reading the following description in light of the accompanying drawing figures, individuals will understand the concepts of the disclosure and will recognize applications of these concepts not particularly addressed herein. It should be understood that these concepts and applications fall within the scope of the disclosure and the accompanying claims.

Any flowcharts discussed herein are necessarily discussed in some sequence for purposes of illustration, but unless otherwise explicitly indicated, the examples and claims are not limited to any particular sequence or order of steps. The use herein of ordinals in conjunction with an element is solely for distinguishing what might otherwise be similar or identical labels, such as “first message” and “second message,” and does not imply an initial occurrence, a quantity, a priority, a type, an importance, or other attribute, unless otherwise stated herein. The term “about” used herein in conjunction with a numeric value means any value that is within a range of ten percent greater than or ten percent less than the numeric value. As used herein and in the claims, the articles “a” and “an” in reference to an element refers to “one or more” of the element unless otherwise explicitly specified. The word “or” as used herein and in the claims is inclusive unless contextually impossible. As an example, the recitation of A or B means A, or B, or both A and B. The word “data” may be used herein in the singular or plural depending on the context. The use of “and/or” between a phrase A and a phrase B, such as “A and/or B” means A alone, B alone, or A and B together.

Machine learning techniques are used to learn complex patterns from data by automatically adapting internal parameters to optimize specific objectives or tasks. Such techniques can be broadly categorized into discriminative models and generative models. Discriminative models focus on understanding the boundary or relationship between input data and the associated output labels, while generative models aim to learn the underlying distribution of the data itself, effectively modeling how the data is produced. By employing these approaches, machine learning systems can perform tasks such as classification, prediction, pattern recognition, and/or a variety of generative tasks (e.g., audio generation, text generation, multimodal generation, etc.).

In particular, discriminative models are often used to classify information into discrete classes of information. Given an unstructured dataset related to a particular complex system, a discriminative model can classify portions of the dataset as belonging to a certain class associated with a specific state of the complex system. For example, if the complex system is a financial system, the discriminative model can classify portions of the dataset as belonging to a “bull” class (e.g., corresponding to a period of market growth) or a “bear” class (e.g., corresponding to a period of market loss). For another example, if the complex system is a manufacturing system, the discriminative model can classify portions of the dataset as belonging to a “productive” class (e.g., corresponding to a period of high manufacturing output) or a “nonproductive” class (e.g., corresponding to a period of low manufacturing output).

Discriminative models can also be used to classify structured datasets in the same manner as unstructured datasets. Typically, given both a structured and unstructured dataset, a machine-learned embedding model can be used to generate vector embeddings to represent both the unstructured content elements and the structured data elements. The vector embeddings generated for both datasets can be stored to a unified hybrid vector database. As described herein, a unified hybrid vector database refers to a vector database that stores vector representations of both structured and unstructured data in a single system. This approach simplifies integration, retrieval, and analysis of diverse data types by unifying their underlying vector-based indexing. As with conventional vector databases, the similarity between two vector representations can be determined based on their distance between each other in the vector database. In other words, the vector database can be (or include) an embedding space for the vector embeddings.

Once vector representations are generated for the structured and unstructured data elements, the discriminative model can process the vector embeddings (and/or the data elements from which the vector embeddings were derived) to generate contextual state labels for the embeddings. The contextual state labels can each indicate a particular system state of the complex system. For example, if the structured and unstructured data elements are associated with a manufacturing system, the contextual state labels can indicate (and/or describe) the system state or various features of the system state when the data element was created. As such, the system states indicated by contextual state labels can be specific to the particular complex system for which they are generated.

For a more specific example, assume that the complex system is a financial system. The structured data elements can include measurements of the financial system (e.g., stock movements over time, current stock prices, etc.), and the unstructured content elements can include comments, forum posts, etc. discussing the system itself and/or components of the system (e.g., individual stocks, regulatory forces, etc.). The data elements can be processed with the machine-learned embedding model to generate the vector representations, and the discriminative model can process the vector embeddings to generate contextual state labels. The contextual state labels can indicate a particular state of the complex system when the data elements were created (e.g., “bull market,” “bear market,” etc.).

Discriminative models can be used in conjunction with generative models to optimize complex systems. In some instances, discriminative models and generative models can be utilized in an adversarial fashion, such as in Generative Adversarial Network (GAN) architectures. In other instances, discriminative models can be utilized to classify and index historical information related to complex systems for utilization as inputs for simulation of those complex systems. For example, assume that an unstructured dataset includes unstructured content elements associated with a manufacturing system (e.g., procedure documentation, user manuals, planning files, related emails or chat logs, etc.). The discriminative model can be used to compute the contextual state labels for the unstructured content elements. Once the contextual state labels are computed, one or more determinant context variable(s) that are at least partially determinant of the contextual state labels can be identified.

A determinant context variable, as described herein, refers to a variable that is at least partially determinant of a corresponding contextual state label of the plurality of contextual state labels. For example, assume that a contextual state label for a manufacturing system indicates “low manufacturing output” for a corresponding structured data element. Further assume that the structured data element includes a water pressure variable with an unusually low value. The water pressure variable can be identified as a determinant context variable that is at least partially determinant of the “low manufacturing output” for the manufacturing system.

A machine-learned generative model can be used to process the determinant context variable(s) and a subset of the vector embeddings to generate a simulation of the particular complex system. The simulation of the particular complex system can be used to evaluate an optimization strategy for the particular complex system. More specifically, the generative model can process the determinant context variables and the vector embeddings to generate a simulation that is based on the information included in the unstructured content elements and/or structured data elements associated with the vector embeddings. To follow the above example, if the determinant context variable processed by the generative model is a water pressure variable with an unusually low value for a manufacturing system, the simulation can simulate the same manufacturing system with the same unusually low value for the water pressure variable.

The simulation can be used to evaluate the optimization strategy for the particular complex system. To follow the previous example, assume that the optimization strategy optimizes water usage within the manufacturing system (e.g., by replacing components of the system, by modifying variables of the system such as flow rate or water pressure, etc.). The optimization strategy can be applied to the simulation of the manufacturing system and can then be evaluated to obtain a strategy evaluation output. The strategy evaluation output can indicate whether the optimization strategy improved (e.g., increased, decreased, etc.) the identified determinant context variable. In such fashion, implementations described herein can leverage a unified hybrid vector database, in conjunction with both discriminative and generative models, to evaluate optimization strategies for complex systems.

Aspects of the present disclosure provide a number of technical effects and benefits. As one example technical effect and benefit, implementations described herein can be used to optimize complex systems, therefore reducing resource utilization within the complex system. To follow the previous example, the manufacturing system can experience a state of “low output” when a water pressure variable is unusually low. In turn, this can degrade performance of the manufacturing system. However, implementations described herein enable simulation of the manufacturing system to evaluate optimization strategies to mitigate the occurrence of such “low output” states. In such fashion, implementations described herein can optimize performance of complex systems.

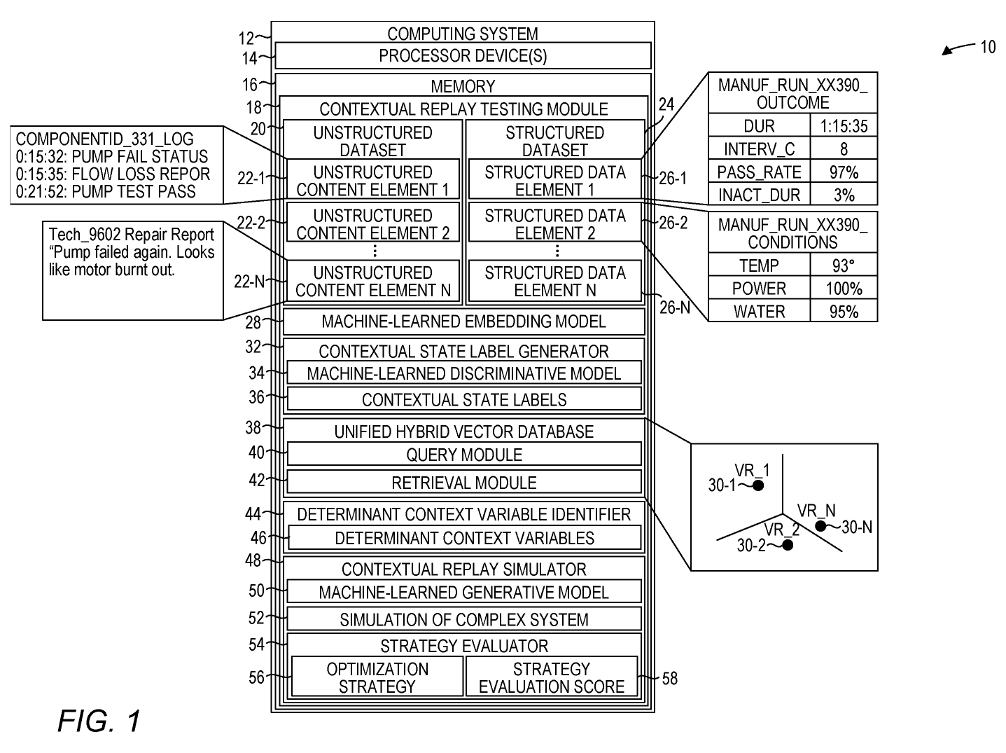

FIG. 1 is a block diagram of a computing environment 10 suitable for implementing a hybrid discriminative and generative model architecture for contextual replay testing in complex systems according to some implementations of the present disclosure. A computing environment 10 can include a computing system 12 with one or more processor device(s) 14 and a memory 16. As described herein, the “computing environment” 10 can be any type or manner of computing environment (e.g., a collection of computing devices, systems, and related infrastructure associated with a particular entity or organization), such as a “confidential” computing environment in which sensitive data and code is protected during processing, a “public” computing environment, etc. For example, the computing environment 10 can be or otherwise include a confidential computing “enclave” that leverages hardware-based execution environments and secure virtualization technologies, such as memory encryption, to isolate critical computations and prevent unauthorized access to data while in use. For another example, the computing environment 10 can be a distributed computing environment that utilizes computing resources across a variety of different types of devices (e.g., servers, virtualized devices, user devices, Internet-of-Things (IoT) devices, etc.).

Additionally, or alternatively, in some implementations, the computing environment 10 can be a cloud computing environment implemented using the computing system 12. For example, the computing system 12 can implement a cloud computing platform by implementing a variety of cloud modules to provide cloud functionality. The cloud computing platform implemented by the computing system 12 can be utilized by various users, entities, organizations, devices, etc. within (and/or external to) the computing environment 10.

In some implementations, the computing system 12 may be a computing device that includes multiple computing devices (i.e., a computing system). Alternatively, in some implementations, the computing system 12 may be one or more computing devices within a computing system that includes multiple computing devices. Similarly, the processor device(s) 14 may include any computing or electronic device capable of executing software instructions to implement the functionality described herein.

The memory 16 can be or otherwise include any device(s) capable of storing data, including, but not limited to, volatile memory (random access memory, etc.), non-volatile memory, storage device(s) (e.g., hard drive(s), solid state drive(s), etc.). In some implementations, the memory 16 can include a containerized unit of software instructions (i.e., a “packaged container”). The containerized unit of software instructions can collectively form a container that has been packaged using any type or manner of containerization technique.

A containerized unit of software instructions can include one or more applications, and can further implement any software or hardware necessary for execution of the containerized unit of software instructions within any type or manner of computing environment. For example, the containerized unit of software instructions can include software instructions that contain or otherwise implement all components necessary for process isolation in any environment (e.g., the application, dependencies, configuration files, libraries, relevant binaries, etc.).

In some implementations, the computing environment 10 can include multiple types of nodes. As described herein, a “node” generally refers to a discrete unit of hardware and/or software resources. In some instances, nodes within the computing environment 10 can be configured to perform specific tasks. For example, some nodes within the computing environment 10 can be configured as “compute” or “processing” nodes that handle processing tasks or provide processing-heavy services. Compute nodes are generally allocated with hardware devices that can facilitate processing tasks, such as Graphics Processing Units (GPUs), Central Processing Units (CPUs), Application-specific Integrated Circuits (ASICs), Field-Programmable Gate Arrays (FPGAs), etc.

Conversely, storage nodes can be allocated with hardware devices to facilitate storage tasks, such as storage devices (e.g., hard drives, etc.), memory, high-bandwidth network devices, physical storage media, etc.). It should be noted that in some instances, storage nodes can include processing devices (e.g., CPUs, etc.) to facilitate storage operations (e.g., read/write operations) and processing nodes can include storage devices (e.g., random access memory) to facilitate processing operations.

The memory 16 can include a contextual replay testing module 18. The contextual replay testing module can perform contextual replay testing of optimization strategies based on simulated scenarios within a complex system. As described herein, a “complex system” refers to any arrangement of interrelated elements with multiple dependencies, including computing elements, logical elements, or physical elements, that exhibits collective behavior emerges from the interplay and interdependence of its constituent parts. Examples of complex systems include distributed computing architectures (e.g., cloud computing frameworks), logical networks (e.g., financial markets or logistical supply chains), and physical infrastructures (e.g., transportation networks or manufacturing systems).

To perform contextual replay testing, the contextual replay testing module can include an unstructured dataset 20. The unstructured dataset 20 can include a plurality of unstructured content elements 22-1 – 22-N (generally, unstructured content elements 22). Unstructured content elements may also be referred to as unstructured data elements. As described herein, an unstructured content element refers to a discrete piece of content that relates to a particular complex system and is not organized according to a predefined data model, schema, or standardized format. Examples of unstructured content elements may include a forum post discussing a financial market, documentation for a manufacturing system, historical records describing the development of a transportation network, etc. Unstructured content elements may exhibit variability in their creation, representation, and contextual details, and sets of contextual content elements may include diverse formats of data elements (e.g., text, images, audio) and/or a lack of standardized metadata or consistent categorization.

For example, assume that the complex system in question is a manufacturing system. Further assume that each of the unstructured content elements 20 are of a different type. One of the unstructured content elements 22-1 may be a forum post from an internal discussion board for discussing possible manufacturing process improvements. Another of the unstructured content elements 22-2 may be a technical manual detailing equipment maintenance procedures. Yet another of the content elements 22-3 may be a blueprint indicating a physical layout of the manufacturing system.

As another example, assume that the complex system is instead a financial system, such as a stock market. Further assume that each of the unstructured content elements 22 are of a different type. One of the unstructured content elements 22-1 may be a social media post analyzing a company’s earnings report. Another of the unstructured content elements 22-2 may be a brokerage research note discussing current market trends. Yet another of the content elements 22-3 may be a transcript from a podcast discussing past market trends.

The contextual replay testing module 18 can also include a structured dataset 24. The structured dataset 24 can include structured data elements 26-1 – 26-N. As described herein, a structured data element refers to any data component that is organized and formatted according to a predefined schema, data model, or standardized structure. Examples of structured data elements can include measurements of a complex system (e.g., power usage for a manufacturing system, market movements for a financial system, etc.), defined system metrics (e.g., a formatted output of a distributed computing system, etc.), sensor readings (e.g., obtained from individual components within a manufacturing system), etc.

The contextual replay testing module 18 can include a machine-learned embedding model 28. The machine-learned embedding model 28 can be any type or manner of machine-learned model, such as a neural network. In particular, the machine-learned embedding model 28 can be a model or a portion of a model (e.g., an encoder portion or embedding portion) trained to process data elements to generate vector representations of the data elements. The contextual replay testing module 18 can process the unstructured content elements 22 and the structured data elements 26 to generate a plurality of vector embeddings 30-1 – 30-N (generally, vector embeddings 30). The vector embeddings 30 can include a first set of vector embeddings corresponding to the unstructured content elements 22 and a second set of embeddings corresponding to the structured data elements 26.

The contextual replay testing module 18 can include a contextual state label generator 32. The contextual state label generator 32 can use a machine-learned discriminative model 34 (e.g., a classifier model such as a multi-layer perceptron, neural network, etc.) to generate a plurality of contextual state labels 36 for the unstructured content elements 20 and the structured data elements 26. As described herein, a “contextual state label” can refer to a label that indicates a particular system state of the complex system that is associated with the corresponding data element. For example, if the complex system is a manufacturing system, the contextual state labels may include labels such as “nominal system output,” “low system output,” “low power usage,” “high power usage,” etc. For another example, if the complex system is financial system, the contextual state labels may include labels such as “bull market” (i.e., a period of market growth), “bear market” (i.e., a period of market shrinkage), “high volatility period”, etc.

In some implementations, the contextual state label 36 generated for a data element can be generated based on the state of the corresponding complex system when the data element was created. For example, if the complex system is a transportation network, and the structured data element 26-1 is a structured sensor reading from an infrastructure element of the network (e.g., a switching component, a track sensor, etc.), the contextual state label 36 can be generated based on the state of the transportation network at the time the sensor reading was created (e.g., a “high traffic” contextual state label if the transportation network was experiencing high traffic when the sensor reading was collected).

Additionally, or alternatively, in some implementations, the contextual state label 36 generated for a data element can be generated based on a state of the corresponding complex system predicted to be correlated with (or correspond to) the data element. For example, if the complex system is a financial system, and the unstructured content element 22-1 is a social media post discussing the occurrence of a new global conflict, the contextual state label 36 may be a “market shrinkage” or “bull market” label that is predicted to correspond to the content of the unstructured content element 22-1.

The machine-learned discriminative model 34 can be any type or manner of machine-learned model, such as a neural network (e.g., deep neural networks) or other types of machine-learned models, including non-linear models and/or linear models. Neural networks can include feed-forward neural networks, recurrent neural networks (e.g., long short-term memory recurrent neural networks), convolutional neural networks or other forms of neural networks. Some example machine-learned models can leverage an attention mechanism such as self-attention. For example, some example machine-learned models can include multi-headed self-attention models (e.g., transformer models).

In some implementations, the machine-learned embedding model 28 can utilize the contextual state labels 36 when generating the vector representations 30. More specifically, the machine-learned embedding model 28 can process a data element and the contextual state labels 36 corresponding to the data element to generate the vector representations 30 for the data element.

The vector embeddings 30 can be stored to a unified hybrid vector database 38 of the contextual replay testing module 18. As described herein, a unified hybrid vector database refers to a data store that maintains vector representations for both unstructured content elements and structured data elements within a single system environment. In such a database, both unstructured and structured data are represented by vector embeddings generated using the machine-learned embedding model 28, thereby enabling consistent indexing, searching, and similarity-based retrieval across disparate types of content.

The unified hybrid vector database 38 can include a query module 40 and a retrieval module 42. In conjunction with retrieval module 42, the query module 40 can obtain queries for the vector database and process the queries to retrieve specific vector representations 30. Additionally, or alternatively, the retrieval module 42 can retrieve the structured data elements 26 and/or the unstructured content elements 22 that are represented by the retrieved vector representations.

Specifically, in some implementations the query module 40 can obtain a query from a user or an automated system. For example, the query module 40 may provide a user interface that can receive a query via user input, receive a query via an Application Programming Interface, etc. For another example, the query module 40 may receive a query from a machine-learned model, such as a generative model (e.g., to facilitate a Retrieval Augmented Generation (RAG) model architecture, etc.). The retrieval module 42 can process the query with the machine-learned embedding model 28, and then perform a similarity search based on the vector representation of the query to retrieve similar vector representations 30 from the unified hybrid vector database 38. The retrieval module 42 can then retrieve corresponding data elements represented by the retrieved vector representations. For example, if the vector representation 30-1 represents the unstructured content element 22-1, and the vector representation 30-1 is retrieved based on the similarity search, the retrieval module 42 can then retrieve the unstructured content element 22-1 (which can be stored to a different data store associated with the unified hybrid vector database).

The contextual replay testing module 18 can include a determinant context variable identifier 44. The determinant context variable identifier 44 can identify determinant context variables 46 for the complex system. More specifically, the determinant context variable identifier 44 can identify the determinant context variables 46 based on the unstructured content elements 22 and/or the structured data elements 26. For example, assume that the structured dataset 20 includes multiple structured data elements 26 that report a water pressure for a manufacturing system. If a “low output” contextual state label is assigned to each structured data element 26 with a “low” water pressure reading, and vice-versa, the water pressure reading can be identified as a determinant context variable. For another example, assume that the structured dataset 20 includes multiple structured data elements 26 that report fluctuating growth rates for a highest ranked set of equities in a financial system. If a “market instability” contextual state label is assigned to each structured data element 26 with a growth rate over a certain fluctuation threshold, the growth rate variable can be identified as a determinant context variable.

The contextual replay testing module 18 can include a contextual replay simulator 48. The contextual replay simulator 48 can use a machine-learned generative model 50 to generate a simulation 52 of the complex system. The machine-learned generative model 50 can be any type of generative model, such as a transformer model, neural network, deep learning model, and/or collection of multiple models. It should be noted that, in some implementations, the simulation 52 can refer to layerwise computations performed by the machine-learned generative model 50 when instructed to simulate a particular scenario within the complex system.

For example, if the complex system is a manufacturing system, the machine-learned generative model 50 may be instructed to simulate a scenario with a particular system state (e.g., a “low output” system state, etc.). The machine-learned generative model 50 can retrieve the unstructured content elements 22 and/or the structured data elements 26 (e.g., via a retrieval augmented generation architecture) with corresponding contextual state labels 36 of the same system state. The machine-learned generative model 50 can also retrieve determinant context variables 46 associated with the particular complex system. The unstructured content elements 22, the structured data elements 26, and/or the determinant context variables 46 can be input to the model as context for simulating the complex system. Alternatively, in some implementations, the machine-learned generative model 50 can iteratively simulate the simulation 60 as the model receives additional prompts or commands.

In some implementations, the simulation 52 can be generated by modifying various determinant context variables of the determinant context variables 46. Specifically, to generate the simulation 52, the contextual replay simulator 48 can modify a value of one (or more) of the determinant context variables 46 identified for the complex system. For example, if the variable is a water pressure variable, the contextual replay simulator 48 can iteratively modify the water pressure variable while simulating the simulation 52.

The contextual replay simulator 48 can include a strategy evaluator 54. The strategy evaluator 54 can evaluate an optimization strategy 56 for the complex system. As described herein, an optimization strategy can refer to an algorithm, procedure, set of rules, or set of modifications for a complex system that are predicted to improve one or more performance metrics of the complex system. The optimization strategy 56 can also adjust or reconfigure components, parameters, or operating conditions of the complex system as simulated in the simulation 52. The optimization strategy 56 may incorporate heuristic or analytical techniques (e.g., gradient-based optimization, evolutionary algorithms, multi-objective optimization) to evaluate potential solutions within the multidimensional space of variables and constraints that characterize the complex system. In some implementations, the optimization strategy 56 can be generated using the machine-learned generative model 50 based on the unstructured content elements 22, the structured data elements 26, and/or the determinant context variables 46.

The optimization strategy 56 can be evaluated by simulating application of the optimization strategy 56 to the simulation 52. More specifically, the optimization strategy 56 can be applied to the simulation 52 while the contextual replay simulator modifies the determinant context variables 46 of the complex system to evaluate the optimization strategy 56 in different conditions. The machine-learned generative model can also be instructed to generate a strategy evaluation score 58. The strategy evaluation score 58 can indicate a degree of optimization provided by the optimization strategy 56. For example, if the complex system is a financial market, and the determinant context variable 46 is a degree of volatility in the market, the strategy evaluation score 58 may indicate that the optimization strategy 56 increases performance of the system during periods of high volatility but decreases performance of the system during periods of low volatility.

In some implementations, the machine-learned generative model 50 can perform a sequence of iterations in which the optimization strategy is adjusted (e.g., by the machine-learned generative model 50 and/or a user of the computing system 12) based on the strategy evaluation score 58 so that the optimization strategy 56 is iteratively improved.

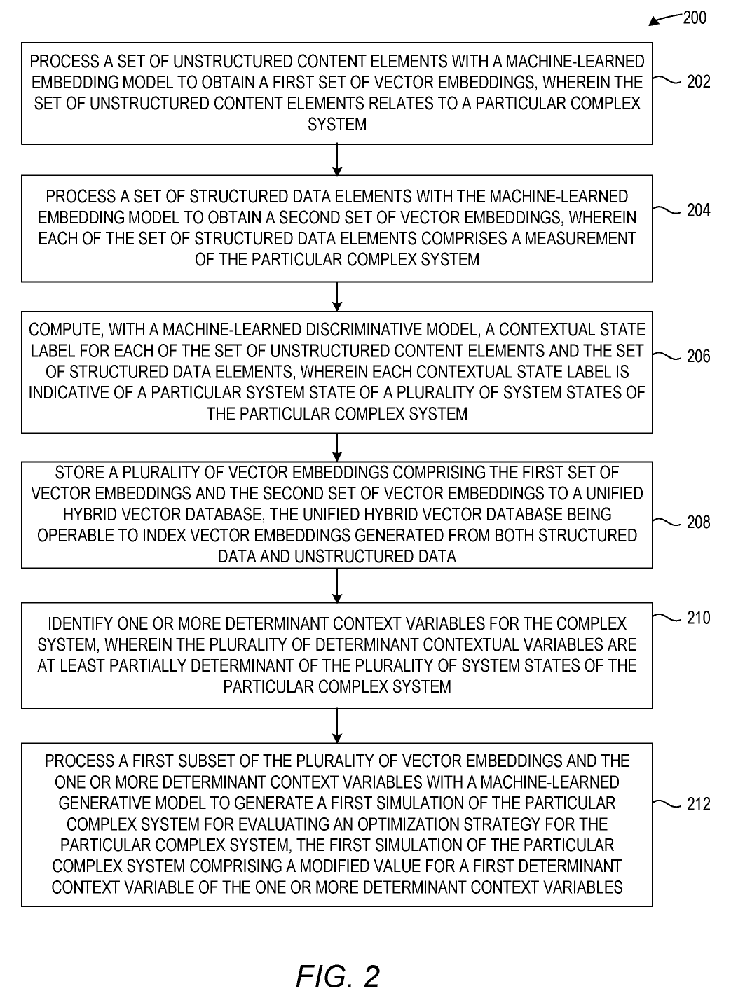

FIG. 2 depicts a flow chart diagram of an example method 200 for contextual replay testing for complex systems using a hybrid discriminative and generative model architecture according to some implementations of the present disclosure. Although FIG. 2 depicts steps performed in a particular order for purposes of illustration and discussion, the methods of the present disclosure are not limited to the particularly illustrated order or arrangement. The various steps of the method 200 can be omitted, rearranged, combined, and/or adapted in various ways without deviating from the scope of the present disclosure.

At 202, a computing system can process a set of unstructured content elements with a machine-learned embedding model to obtain a first set of vector embeddings. The set of unstructured content elements can relate to a particular complex system.

In some implementations, prior to processing the first subset of the plurality of vector embeddings and the plurality of determinant context variables with the machine-learned generative model, the computing system can train the machine-learned generative model with the machine-learned discriminative model. To train the machine-learned generative model, the computing system can process a set of training data with the machine-learned generative model to obtain a training output. The computing system can evaluate the training output with the machine-learned discriminative model to obtain a feedback output. The computing system can train the machine-learned generative model based on the feedback output.

In some implementations, the particular complex system comprises a manufacturing system, and the optimization strategy comprises an arrangement of components of the manufacturing system. In some implementations, the particular complex system comprises a communications network, and wherein the optimization strategy comprises an arrangement of communication links within the communications network. In some implementations, the particular complex system comprises a financial system, and the optimization strategy comprises a set of rules for automated interactions within the financial system.

At 204, the computing system can process a set of structured data elements with the machine-learned embedding model to obtain a second set of vector embeddings, wherein each of the set of structured data elements comprises a measurement of the particular complex system

At 206, the computing system can compute, with a machine-learned discriminative model, a contextual state label for each of the set of unstructured content elements and the set of structured data elements. Each contextual state label is indicative of a particular system state of a plurality of system states of the particular complex system.

At 208, the computing system can store a plurality of vector embeddings comprising the first set of vector embeddings and the second set of vector embeddings to a unified hybrid vector database. The unified hybrid vector database is operable to index vector embeddings generated from both structured data and unstructured data.

At 210, the computing system can identify one or more determinant context variables for the complex system. The plurality of determinant contextual variables are at least partially determinant of the plurality of system states of the particular complex system.

At 212, the computing system can process a first subset of the plurality of vector embeddings and the one or more determinant context variables with a machine-learned generative model to generate a first simulation of a scenario within the particular complex system for evaluating an optimization strategy for the particular complex system. The first simulation of the particular complex system can include a modified value for a first determinant context variable of the one or more determinant context variables.

In some implementations, processing the first subset of the plurality of vector embeddings and the plurality of determinant context variables with the machine-learned generative model to generate the first simulation of the particular complex system comprises determining the modified value to replace the existing value for the first determinant context variable of the plurality of determinant context variables. In some implementations, determining the modified value includes selecting the first determinant context variable from the one or more determinant context variables and generating the modified value to replace the existing value for the first determinant context variable.

In some implementations, to determine the modified value, the computing system can retrieve the first subset of vector embeddings from the plurality of vector embeddings stored to the unified hybrid vector database. The first subset of vector embeddings is retrieved based on a similarity between the modified value for the first determinant context variable and a subset of the plurality of contextual state labels respectively associated with the subset of vector embeddings.

In some implementations, to identify the one or more determinant context variables respectively associated with the plurality of vector embeddings, the computing system can cause display of a plurality of selectable interface elements respectively representing the plurality of determinant context variables. For example, the computing system may display the selectable interface elements via a display device. For another example, the computing system can provide the selectable interface elements at a user device associated with a user of the computing system. The computing system can receive a first user input indicative of selection of a first selectable interface element that represents the first determinant context variable from the plurality of selectable interface elements. The computing system can receive a second user input indicative of the modified value.

In some implementations, the computing system can further process a second subset of the plurality of vector embeddings and the one or more determinant context variables with the machine-learned generative model to generate a second simulation of the particular complex system for evaluating the optimization strategy for the particular complex system. The second subset of vector embeddings are retrieved based on a similarity between the existing value for the first determinant context variable and a second subset of the plurality of contextual state labels respectively associated with the second subset of vector embeddings. The computing system can evaluate the optimization strategy based on a difference between the first simulation and the second simulation.

In some implementations, to evaluate the optimization strategy, the computing system can apply the optimization strategy to the first simulation of the particular complex system to obtain a first strategy evaluation output. The computing system can apply the optimization strategy to the second simulation of the particular complex system to obtain a second strategy evaluation output. The computing system can generate a strategy evaluation score for the optimization strategy based on a difference between the first strategy evaluation output and the second strategy evaluation output.

In some implementations, to apply the optimization strategy to the first simulation of the particular complex system to obtain the first strategy evaluation output, the computing system can process information descriptive of the optimization strategy and the first simulation of the particular complex system with the machine-learned generative model to obtain the first strategy evaluation output.

In some implementations, the strategy evaluation score comprises an aggregate evaluation score derived from a plurality of sub-scores respectively associated with the plurality of determinant context variables. To process the information descriptive of the optimization strategy and the first simulation of the particular complex system with the machine-learned generative model to obtain the first strategy evaluation output, the computing system can process the information descriptive of the optimization strategy and the first simulation of the particular complex system with the machine-learned generative model to obtain a first sub-score of the plurality of sub-scores. The first sub-score is indicative of a degree of performance for the optimization strategy relative to the first determinant context variable.

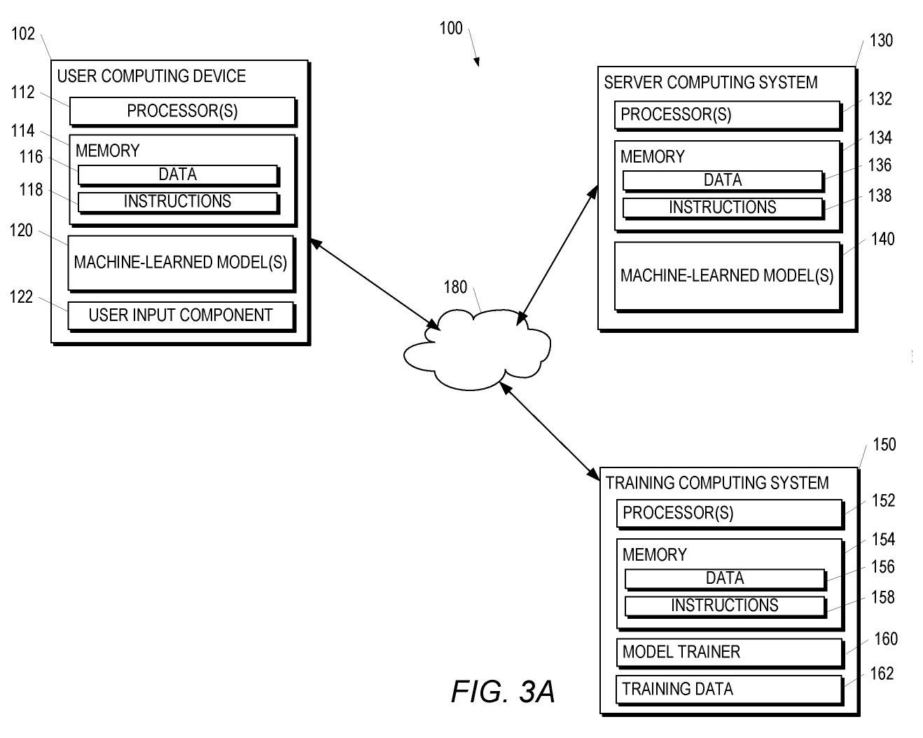

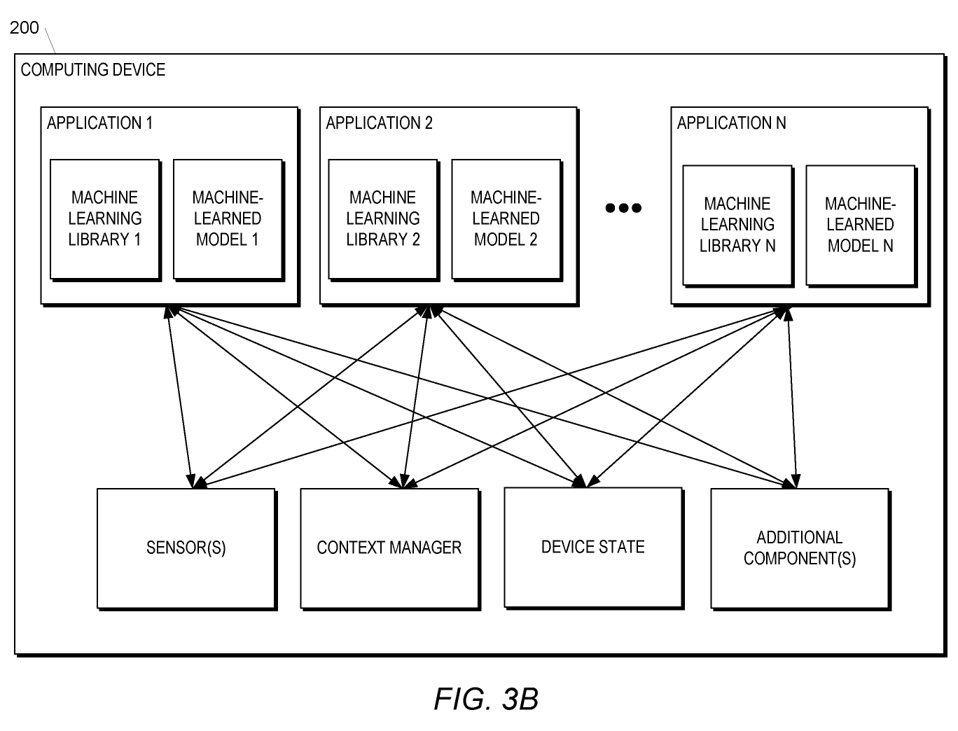

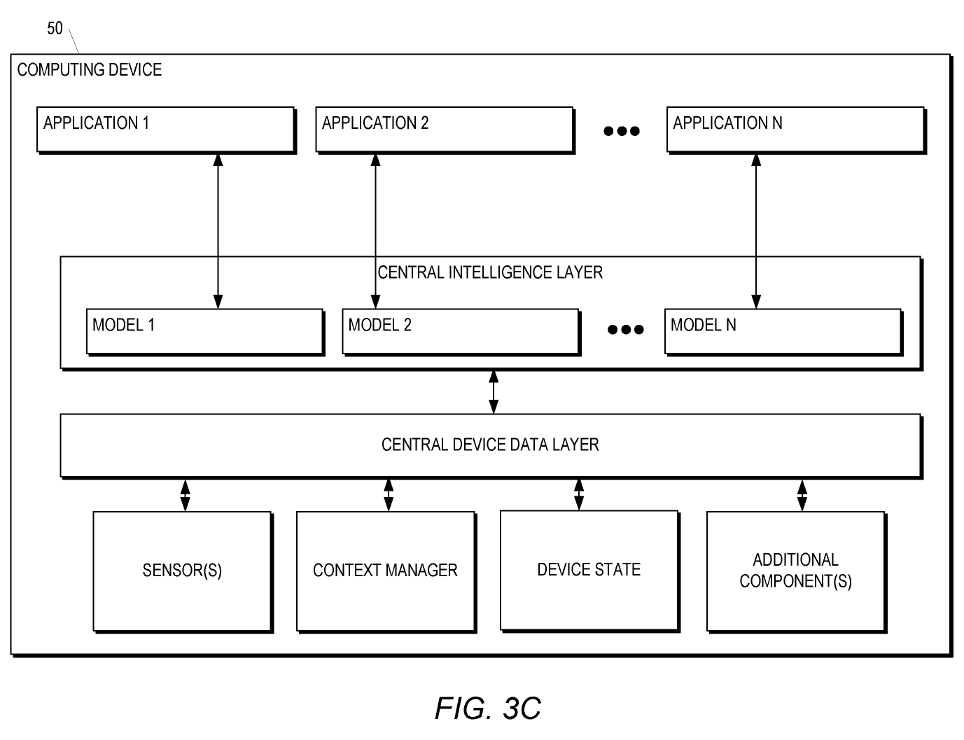

FIG. 3A depicts a block diagram of an example computing system 100 that performs contextual replay testing according to example embodiments of the present disclosure. The system 100 includes a user computing device 102, a server computing system 130, and a training computing system 150 that are communicatively coupled over a network 180.

The user computing device 102 can be any type of computing device, such as, for example, a personal computing device (e.g., laptop or desktop), a mobile computing device (e.g., smartphone or tablet), a gaming console or controller, a wearable computing device, an embedded computing device, or any other type of computing device.

The user computing device 102 includes one or more processors 112 and a memory 114. The one or more processors 112 can be any suitable processing device (e.g., a processor core, a microprocessor, an ASIC, an FPGA, a controller, a microcontroller, etc.) and can be one processor or a plurality of processors that are operatively connected. The memory 114 can include one or more non-transitory computer-readable storage media, such as RAM, ROM, EEPROM, EPROM, flash memory devices, magnetic disks, etc., and combinations thereof. The memory 114 can store data 116 and instructions 118 which are executed by the processor 112 to cause the user computing device 102 to perform operations.

In some implementations, the user computing device 102 can store or include one or more generative and discriminative models 120. For example, the generative and discriminative models 120 can be or can otherwise include various machine-learned models such as neural networks (e.g., deep neural networks) or other types of machine-learned models, including non-linear models and/or linear models. Neural networks can include feed-forward neural networks, recurrent neural networks (e.g., long short-term memory recurrent neural networks), convolutional neural networks or other forms of neural networks. Some example machine-learned models can leverage an attention mechanism such as self-attention. For example, some example machine-learned models can include multi-headed self-attention models (e.g., transformer models).

In some implementations, the one or more generative and discriminative models 120 can be received from the server computing system 130 over network 180, stored in the user computing device memory 114, and then used or otherwise implemented by the one or more processors 112. In some implementations, the user computing device 102 can implement multiple parallel instances of a single generative or discriminative model 120 (e.g., to perform parallel generative or discriminative tasks).

Additionally or alternatively, one or more generative and discriminative models 140 can be included in or otherwise stored and implemented by the server computing system 130 that communicates with the user computing device 102 according to a client-server relationship. For example, the models 140 can be implemented by the server computing system 140 as a portion of a web service. Thus, one or more models 120 can be stored and implemented at the user computing device 102 and/or one or more models 140 can be stored and implemented at the server computing system 130.

The user computing device 102 can also include one or more user input components 122 that receives user input. For example, the user input component 122 can be a touch-sensitive component (e.g., a touch-sensitive display screen or a touch pad) that is sensitive to the touch of a user input object (e.g., a finger or a stylus). The touch-sensitive component can serve to implement a virtual keyboard. Other example user input components include a microphone, a traditional keyboard, or other means by which a user can provide user input.

The server computing system 130 includes one or more processors 132 and a memory 134. The one or more processors 132 can be any suitable processing device (e.g., a processor core, a microprocessor, an ASIC, an FPGA, a controller, a microcontroller, etc.) and can be one processor or a plurality of processors that are operatively connected. The memory 134 can include one or more non-transitory computer-readable storage media, such as RAM, ROM, EEPROM, EPROM, flash memory devices, magnetic disks, etc., and combinations thereof. The memory 134 can store data 136 and instructions 138 which are executed by the processor 132 to cause the server computing system 130 to perform operations.

In some implementations, the server computing system 130 includes or is otherwise implemented by one or more server computing devices. In instances in which the server computing system 130 includes plural server computing devices, such server computing devices can operate according to sequential computing architectures, parallel computing architectures, or some combination thereof.

As described above, the server computing system 130 can store or otherwise include one or more models 140. For example, the models 140 can be or can otherwise include various machine-learned models. Example machine-learned models include neural networks or other multi-layer non-linear models. Example neural networks include feed forward neural networks, deep neural networks, recurrent neural networks, and convolutional neural networks. Some example machine-learned models can leverage an attention mechanism such as self-attention. For example, some example machine-learned models can include multi-headed self-attention models (e.g., transformer models).

The user computing device 102 and/or the server computing system 130 can train the models 120 and/or 140 via interaction with the training computing system 150 that is communicatively coupled over the network 180. The training computing system 150 can be separate from the server computing system 130 or can be a portion of the server computing system 130.

The training computing system 150 includes one or more processors 152 and a memory 154. The one or more processors 152 can be any suitable processing device (e.g., a processor core, a microprocessor, an ASIC, an FPGA, a controller, a microcontroller, etc.) and can be one processor or a plurality of processors that are operatively connected. The memory 154 can include one or more non-transitory computer-readable storage media, such as RAM, ROM, EEPROM, EPROM, flash memory devices, magnetic disks, etc., and combinations thereof. The memory 154 can store data 156 and instructions 158 which are executed by the processor 152 to cause the training computing system 150 to perform operations. In some implementations, the training computing system 150 includes or is otherwise implemented by one or more server computing devices.

The training computing system 150 can include a model trainer 160 that trains the machine-learned models 120 and/or 140 stored at the user computing device 102 and/or the server computing system 130 using various training or learning techniques, such as, for example, backwards propagation of errors. For example, a loss function can be backpropagated through the model(s) to update one or more parameters of the model(s) (e.g., based on a gradient of the loss function). Various loss functions can be used such as mean squared error, likelihood loss, cross entropy loss, hinge loss, and/or various other loss functions. Gradient descent techniques can be used to iteratively update the parameters over a number of training iterations.

In some implementations, performing backwards propagation of errors can include performing truncated backpropagation through time. The model trainer 160 can perform a number of generalization techniques (e.g., weight decays, dropouts, etc.) to improve the generalization capability of the models being trained. In particular, the model trainer 160 can train the models 120 and/or 140 based on a set of training data 162.

In some implementations, if the user has provided consent, the training examples can be provided by the user computing device 102. Thus, in such implementations, the model 120 provided to the user computing device 102 can be trained by the training computing system 150 on user-specific data received from the user computing device 102. In some instances, this process can be referred to as personalizing the model.

The model trainer 160 includes computer logic utilized to provide desired functionality. The model trainer 160 can be implemented in hardware, firmware, and/or software controlling a general purpose processor. For example, in some implementations, the model trainer 160 includes program files stored on a storage device, loaded into a memory and executed by one or more processors. In other implementations, the model trainer 160 includes one or more sets of computer-executable instructions that are stored in a tangible computer-readable storage medium such as RAM, hard disk, or optical or magnetic media.

The network 180 can be any type of communications network, such as a local area network (e.g., intranet), wide area network (e.g., Internet), or some combination thereof and can include any number of wired or wireless links. In general, communication over the network 180 can be carried via any type of wired and/or wireless connection, using a wide variety of communication protocols (e.g., TCP/IP, HTTP, SMTP, FTP), encodings or formats (e.g., HTML, XML), and/or protection schemes (e.g., VPN, secure HTTP, SSL).

FIG. 1A illustrates one example computing system that can be used to implement the present disclosure. Other computing systems can be used as well. For example, in some implementations, the user computing device 102 can include the model trainer 160 and the training dataset 162. In such implementations, the models 120 can be both trained and used locally at the user computing device 102. In some of such implementations, the user computing device 102 can implement the model trainer 160 to personalize the models 120 based on user-specific data.

FIG. 3B depicts a block diagram of an example computing device 200 that performs contextual replay testing according to example embodiments of the present disclosure. The computing device 200 can be a user computing device or a server computing device.

The computing device 200 includes a number of applications (e.g., applications 1 through N). Each application contains its own machine learning library and machine-learned model(s). For example, each application can include a machine-learned model. Example applications include a text messaging application, an email application, a dictation application, a virtual keyboard application, a browser application, etc.

As illustrated in FIG. 3B, each application can communicate with a number of other components of the computing device, such as, for example, one or more sensors, a context manager, a device state component, and/or additional components. In some implementations, each application can communicate with each device component using an API (e.g., a public API). In some implementations, the API used by each application is specific to that application.

FIG. 3C depicts a block diagram of an example computing device 250 that performs training of generative and discriminative models according to example embodiments of the present disclosure. The computing device 250 can be a user computing device or a server computing device.

The computing device 250 includes a number of applications (e.g., applications 1 through N). Each application is in communication with a central intelligence layer. Example applications include a text messaging application, an email application, a dictation application, a virtual keyboard application, a browser application, etc. In some implementations, each application can communicate with the central intelligence layer (and model(s) stored therein) using an API (e.g., a common API across all applications).

The central intelligence layer includes a number of machine-learned models. For example, as illustrated in FIG. 3C, a respective machine-learned model can be provided for each application and managed by the central intelligence layer. In other implementations, two or more applications can share a single machine-learned model. For example, in some implementations, the central intelligence layer can provide a single model for all of the applications. In some implementations, the central intelligence layer is included within or otherwise implemented by an operating system of the computing device 250.

The central intelligence layer can communicate with a central device data layer. The central device data layer can be a centralized repository of data for the computing device 250. As illustrated in FIG. 3C, the central device data layer can communicate with a number of other components of the computing device, such as, for example, one or more sensors, a context manager, a device state component, and/or additional components. In some implementations, the central device data layer can communicate with each device component using an API (e.g., a private API).

Individuals will recognize improvements and modifications to the preferred examples of the disclosure. All such improvements and modifications are considered within the scope of the concepts disclosed herein and the claims that follow.

What is claimed is:

1. A method, comprising:
processing, by a computing system comprising one or more processor devices, a set of unstructured content elements with a machine-learned embedding model to obtain a first set of vector embeddings, wherein the set of unstructured content elements relates to a particular complex system;
processing, by the computing system, a set of structured data elements with the machine-learned embedding model to obtain a second set of vector embeddings, wherein each of the set of structured data elements comprises a measurement of the particular complex system;
computing, by the computing system with a machine-learned discriminative model, a contextual state label for each of the set of unstructured content elements and the set of structured data elements, wherein each contextual state label is indicative of a particular system state of a plurality of system states of the particular complex system;
storing, by the computing system, a plurality of vector embeddings comprising the first set of vector embeddings and the second set of vector embeddings to a unified hybrid vector database, the unified hybrid vector database being operable to index vector embeddings generated from both structured data and unstructured data;
identifying, by the computing system, one or more determinant context variables for the complex system, wherein the plurality of determinant contextual variables are at least partially determinant of the plurality of system states of the particular complex system; and
processing, by the computing system, a first subset of the plurality of vector embeddings and the one or more determinant context variables with a machine-learned generative model to generate a first simulation of the particular complex system for evaluating an optimization strategy for the particular complex system, the first simulation of the particular complex system comprising a modified value for a first determinant context variable of the one or more determinant context variables.

2. The method of claim 1, wherein processing the first subset of the plurality of vector embeddings and the one or more determinant context variables with the machine-learned generative model to generate the first simulation of the particular complex system comprises:
determining, by the computing system, the modified value to replace the existing value for the first determinant context variable of the one or more determinant context variables.

3. The method of claim 2, wherein determining the modified value to replace the existing value comprises:
selecting, by the computing system, the first determinant context variable from the one or more determinant context variables; and
generating, by the computing system, the modified value to replace the existing value for the first determinant context variable.

4. The method of claim 3, wherein identifying the one or more determinant context variables comprises:
causing, by the computing system, display of one or more selectable interface elements respectively representing the one or more determinant context variables; and
receiving, by the computing system, a first user input indicative of selection of a first selectable interface element from the one or more selectable interface elements that represents the first determinant context variable.

5. The method of claim 4, wherein generating the modified value to replace the existing value for the first determinant context variable comprises:
receiving, by the computing system, a second user input indicative of the modified value.

6. The method of claim 2, wherein determining the modified value to replace the existing value for the first determinant context variable of the one or more determinant context variables further comprises:
retrieving, by the computing system, the first subset of vector embeddings from the plurality of vector embeddings stored to the unified hybrid vector database, wherein the first subset of vector embeddings are retrieved based on a similarity between the modified value for the first determinant context variable and a subset of the plurality of contextual state labels respectively associated with the subset of vector embeddings.

7. The method of claim 2, wherein the method further comprises:
processing, by the computing system, a second subset of the plurality of vector embeddings and the one or more determinant context variables with the machine-learned generative model to generate a second simulation of the particular complex system for evaluating the optimization strategy for the particular complex system, wherein the second subset of vector embeddings are retrieved based on a similarity between the existing value for the first determinant context variable and a second subset of the plurality of contextual state labels respectively associated with the second subset of vector embeddings; and
evaluating, by the computing system, the optimization strategy based on a difference between the first simulation and the second simulation.

8. The method of claim 7, wherein evaluating the optimization strategy based on the difference between the first simulation and the second simulation comprises:
applying, by the computing system, the optimization strategy to the first simulation of the particular complex system to obtain a first strategy evaluation output;
applying, by the computing system, the optimization strategy to the second simulation of the particular complex system to obtain a second strategy evaluation output; and
generating, by the computing system, a strategy evaluation score for the optimization strategy based on a difference between the first strategy evaluation output and the second strategy evaluation output.

9. The method of claim 8, wherein applying the optimization strategy to the first simulation of the particular complex system to obtain the first strategy evaluation output comprises:
processing, by the computing system, information descriptive of the optimization strategy and the first simulation of the particular complex system with the machine-learned generative model to obtain the first strategy evaluation output.

10. The method of claim 9, wherein the strategy evaluation score comprises an aggregate evaluation score derived from a plurality of sub-scores respectively associated with the plurality of determinant context variables; and
wherein processing the information descriptive of the optimization strategy and the first simulation of the particular complex system with the machine-learned generative model to obtain the first strategy evaluation output comprises:
processing, by the computing system, the information descriptive of the optimization strategy and the first simulation of the particular complex system with the machine-learned generative model to obtain a first sub-score of the plurality of sub-scores, wherein the first sub-score is indicative of a degree of performance for the optimization strategy relative to the first determinant context variable.

11. The method of claim 1, wherein, prior to processing the first subset of the plurality of vector embeddings and the plurality of determinant context variables with the machine-learned generative model, the method comprises:
training, by the computing system, the machine-learned generative model with the machine-learned discriminative model, wherein training the machine-learned generative model comprises:
processing, by the computing system, a set of training data with the machine-learned generative model to obtain a training output;
evaluating, by the computing system, the training output with the machine-learned discriminative model to obtain a feedback output; and
training, by the computing system, the machine-learned generative model based on the feedback output.

12. The method of claim 1, wherein the particular complex system comprises a manufacturing system, and wherein the optimization strategy comprises an arrangement of components of the manufacturing system.

13. The method of claim 1, wherein the particular complex system comprises a communications network, and wherein the optimization strategy comprises an arrangement of communication links within the communications network.

14. The method of claim 1, wherein the particular complex system comprises a financial system, and wherein the optimization strategy comprises a set of rules for automated interactions within the financial system.

15. A computing system comprising:
one or more processor devices configured to:
process a set of unstructured content elements with a machine-learned embedding model to obtain a first set of vector embeddings, wherein the set of unstructured content elements relates to a particular complex system;
process a set of structured data elements with the machine-learned embedding model to obtain a second set of vector embeddings, wherein each of the set of structured data elements comprises a measurement of the particular complex system;
compute, with a machine-learned discriminative model, a contextual state label for each of the set of unstructured content elements and the set of structured data elements, wherein each contextual state label is indicative of a particular system state of a plurality of system states of the particular complex system;
store a plurality of vector embeddings comprising the first set of vector embeddings and the second set of vector embeddings to a unified hybrid vector database, the unified hybrid vector database being operable to index vector embeddings generated from both structured data and unstructured data;
identify one or more determinant context variables for the complex system, wherein the plurality of determinant contextual variables are at least partially determinant of the plurality of system states of the particular complex system; and
process a first subset of the plurality of vector embeddings and the one or more determinant context variables with a machine-learned generative model to generate a first simulation of the particular complex system for evaluating an optimization strategy for the particular complex system, the first simulation of the particular complex system comprising a modified value for a first determinant context variable of the one or more determinant context variables.

16. The computing system of claim 15, wherein processing the first subset of the plurality of vector embeddings and the one or more determinant context variables with the machine-learned generative model to generate the first simulation of the particular complex system comprises:
determining the modified value to replace the existing value for the first determinant context variable of the one or more determinant context variables.

17. The computing system of claim 16, wherein determining the modified value to replace the existing value comprises:
selecting the first determinant context variable from the one or more determinant context variables; and
generating, by the computing system, the modified value to replace the existing value for the first determinant context variable.

18. The computing system of claim 17, wherein identifying the one or more determinant context variables comprises:
causing display of one or more selectable interface elements respectively representing the one or more determinant context variables; and
receiving a first user input indicative of selection of a first selectable interface element from the one or more selectable interface elements that represents the first determinant context variable.

19. The computing system of claim 18, wherein generating the modified value to replace the existing value for the first determinant context variable comprises:
receiving a second user input indicative of the modified value.

20. A non-transitory computer-readable storage medium that includes executable instructions configured to cause one or more processor devices to:
process a set of unstructured content elements with a machine-learned embedding model to obtain a first set of vector embeddings, wherein the set of unstructured content elements relates to a particular complex system;
process a set of structured data elements with the machine-learned embedding model to obtain a second set of vector embeddings, wherein each of the set of structured data elements comprises a measurement of the particular complex system;
compute, with a machine-learned discriminative model, a contextual state label for each of the set of unstructured content elements and the set of structured data elements, wherein each contextual state label is indicative of a particular system state of a plurality of system states of the particular complex system;
store a plurality of vector embeddings comprising the first set of vector embeddings and the second set of vector embeddings to a unified hybrid vector database, the unified hybrid vector database being operable to index vector embeddings generated from both structured data and unstructured data;
identify one or more determinant context variables for the complex system, wherein the plurality of determinant contextual variables are at least partially determinant of the plurality of system states of the particular complex system; and
process a first subset of the plurality of vector embeddings and the one or more determinant context variables with a machine-learned generative model to generate a first simulation of the particular complex system for evaluating an optimization strategy for the particular complex system, the first simulation of the particular complex system comprising a modified value for a first determinant context variable of the one or more determinant context variables.
